(19) United States
(12) Patent Application Publication
(10) Pub. No.: US 2024/0192322 A1
(43) Pub. Date: Jun. 13, 2024

(54) LASER RADAR MODULE

(71) Applicant: Cloud Light Technology Limited, Hong Kong (HK)

(72) Inventors: Chong Yang Qin, Dongguan (CN); Xian Wen Feng, Dongguan (CN)

(21) Appl. No.: 18/528,699

(22) Filed: Dec. 4, 2023

(30) Foreign Application Priority Data
Dec. 9, 2022 (CN) 202211591742.7

(51) Int. Cl. G01S 7/481; H05K 5/00; H05K 5/06; H05K 7/20; H05K 9/00

(52) U.S. Cl. CPC G01S 7/4813; H05K 5/0008; H05K 5/0021; H05K 5/061; H05K 7/20418; H05K 9/0032; H05K 9/0058; H01S 5/02415

(57) ABSTRACT

The present disclosure provides a laser radar module, including a housing body; a laser transceiver assembly and a thermoelectric cooler temperature control assembly accommodated in the housing body, the laser transceiver assembly and the thermoelectric cooler temperature control assembly being stacked and in contact with each other; an upper cover of a sealed chamber accommodated in the housing body and fixedly connected on an inner wall of the housing body, the upper cover of the sealed chamber and the housing body together enclosing and sealing the laser transceiver assembly; and a first circuit board and a second circuit board that are stacked and electrically connected to each other for electrically controlling the laser transceiver assembly and the thermoelectric cooler temperature control assembly respectively. An object of the present disclosure is to provide a laser radar module to at least reduce the size of the laser radar module.

### CROSS REFERENCE TO RELATED APPLICATIONS

The present application claims the benefit of Chinese Patent Application No. 202211591742.7 filed on Dec. 9, 2022, the contents of which are incorporated herein by reference in their entirety.

### TECHNICAL FIELD

The present disclosure relates to the field of detection technology, in particular to a laser radar module.

### BACKGROUND TECHNOLOGY

A laser radar emits a laser beam (single-line/multi-line) to a target, then compares a reflected signal with the emitted signal and analyzes the return time (TOF) or frequency difference (Doppler frequency shift) of the signal to obtain the target distance, speed, and other related parameters. With the continuous development of technologies such as intelligent driving and intelligent robots, there is an increasingly higher requirement of the cost, size and power consumption of a laser radar as a core sensor, especially the structural form of the laser radar, there is an urgent need for a small size laser radar module to suit different scenarios.

### SUMMARY

In view of the problem existing in the related art, an object of the present disclosure is to provide a laser radar module to at least reduce the size of the laser radar module.

In order to achieve the above object, the present application provides a laser radar module, including a housing body; a laser transceiver assembly and a thermoelectric cooler temperature control assembly accommodated in the housing body, the laser transceiver assembly and the thermoelectric cooler temperature control assembly being stacked and in contact with each other; an upper cover of a sealed chamber accommodated in the housing body and fixedly connected on an inner wall of the housing body, the upper cover of the sealed chamber and the housing body together enclosing and sealing the laser transceiver assembly; and a circuit board accommodated in the housing body and disposed side by side with the stacked laser transceiver assembly and thermoelectric cooler temperature control assembly, and configured to electrically control the laser transceiver assembly and the thermoelectric cooler temperature control assembly.

In some embodiments, the circuit board may include a first circuit board and a second circuit board that are stacked and electrically connected to each other for electrically controlling the laser transceiver assembly and the thermoelectric cooler temperature control assembly respectively; the housing body includes a first outer housing and a second outer housing that are fixedly connected to each other; the laser transceiver assembly, the thermoelectric cooler temperature control assembly, the first circuit board, and the second circuit board are located between the first outer housing and the second outer housing; and the upper cover of the sealed chamber and a portion of the second outer housing together form the sealed chamber, and enclose and seal the laser transceiver assembly and the thermoelectric cooler temperature control assembly.

In some embodiments, the laser radar module may further include a first electromagnetic shield and a second electromagnetic shield fixed on the first circuit board and the second circuit board respectively, the first electromagnetic shield and the second electromagnetic shield being located between the first circuit board and the second circuit board.

In some embodiments, the first outer housing has a first opening, one side of the upper cover of the sealed chamber facing away from the second outer housing is provided with fins, and the fins are exposed from the first opening.

In some embodiments, the laser radar module may further include a support plate fixed on the second outer housing and supporting the first circuit board.

In some embodiments, the circuit board may include a first circuit board and a second circuit board that are stacked and electrically connected to each other for electrically controlling the laser transceiver assembly and the thermoelectric cooler temperature control assembly respectively, the housing body includes a first outer housing, a second outer housing and a third outer housing that are fixed together, the second outer housing being located between the first outer housing and the third outer housing, the laser transceiver assembly and the first circuit board are located between the first outer housing and the second outer housing, the thermoelectric cooler temperature control assembly and the second circuit board are located between the third outer housing and the second outer housing, and the upper cover of the sealed chamber and a portion of the second outer housing together form the sealed chamber, and enclose and seal the laser transceiver assembly.

In some embodiments, the second outer housing includes a second opening and a third opening, the laser transceiver assembly can be in contact with the thermoelectric cooler temperature control assembly through the second opening, and the first circuit board can be electrically connected to the second circuit board through the third opening.

In some embodiments, the second outer housing and the first outer housing surround and form a first chamber that accommodates the first circuit board, and the second outer housing and the third outer housing surround and form a second chamber that accommodates the second circuit board.

In some embodiments, the sealed chamber and the first chamber are separated by a step structure of the second outer housing protruding toward the first circuit board.

In some embodiments, the laser radar module may further include a sealing rubber body provided at a position where the upper cover of the sealed chamber and the second outer housing are joined to each other.

### DESCRIPTION OF THE DRAWINGS

The aspects of the present disclosure are best understood from the following detailed description when read in conjunction with the accompanying drawings. It should be noted that, in accordance with standard practice in the industry, various components may not be drawn to scale. Indeed, the dimensions of various components may be arbitrarily increased or decreased for clarity of discussion.

FIG. 1 shows a perspective view of a laser radar module 100 provided by a first embodiment of the present disclosure;

FIG. 2 shows a perspective view on the basis of FIG. 1 after removal of a first outer housing 11;

FIG. 3 shows a perspective view on the basis of FIG. 2 after removal of an upper cover 20 of a sealed chamber;

FIG. 4 shows a perspective view of the upper cover 20 of the sealed chamber;

FIG. 5 shows a perspective view of a second outer housing 12;

FIG. 6 shows a front view of the laser radar module 100, in which the visible structures in the front view are shown by thicker lines, and the invisible structures in the front view are shown by thinner lines;

FIG. 7 shows an exploded view of the laser radar module 100;

FIG. 8 shows a perspective view of the laser radar module provided by a second embodiment of the present disclosure;

FIG. 9 shows a perspective view on the basis of FIG. 8 after removal of a first outer housing;

FIG. 10 shows a perspective view on the basis of FIG. 9 after removal of an upper cover of a sealed chamber;

FIG. 11 shows a front view of a second outer housing, in which the visible structures in the front view are shown by thicker lines, and the invisible structures in the front view are shown by thinner lines;

FIG. 12 shows a perspective view of the second outer housing viewed from an upper side of FIG. 11;

FIG. 13 shows a cross-sectional view of the second outer housing;

FIG. 14 shows a perspective view of the second outer housing viewed from a lower side of FIG. 11;

FIG. 15 shows a front view of the laser radar module, in which the visible structures in the front view are shown by thicker lines, and the invisible structures in the front view are shown by thinner lines;

FIG. 16 shows an exploded view of the laser radar module.

### DETAILED DESCRIPTION OF EMBODIMENTS

The following disclosure provides many different embodiments or examples for implementing different features of the provided subject matter. Specific examples of elements and arrangements are described below to simplify the disclosure. Of course, these are merely examples and are not intended to limit the disclosure. For example, in the following description, forming a first component over or on a second component may include embodiments in which the first component and the second component are in direct contact with each other, or may include forming an additional component between the first component and the second component, in which the first component and the second component may not be in direct contact with each other. Furthermore, the present application may repeat reference numbers and/or letters in each example. This repetition is for simplicity and clarity only and does not in itself represent a relationship between various embodiments and/or configurations discussed.

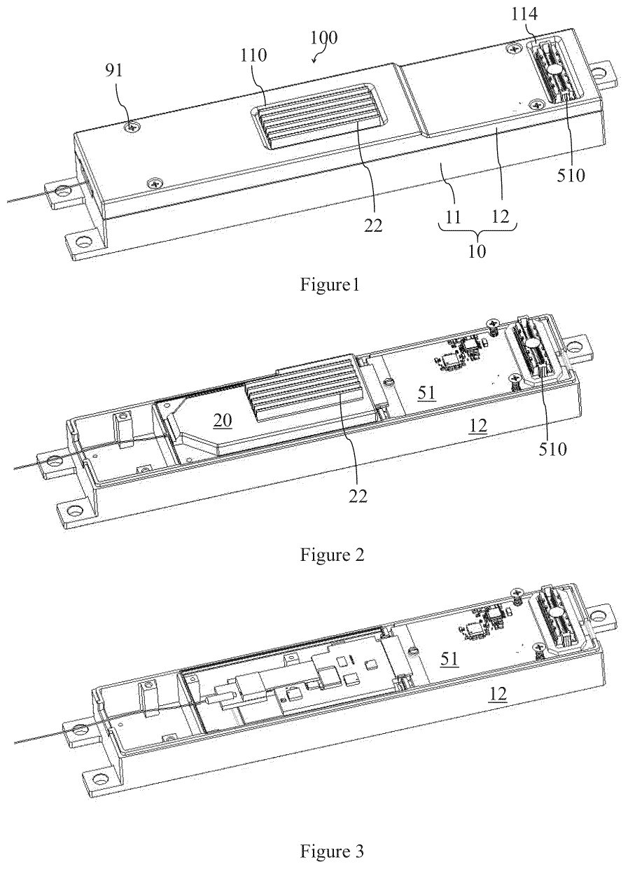

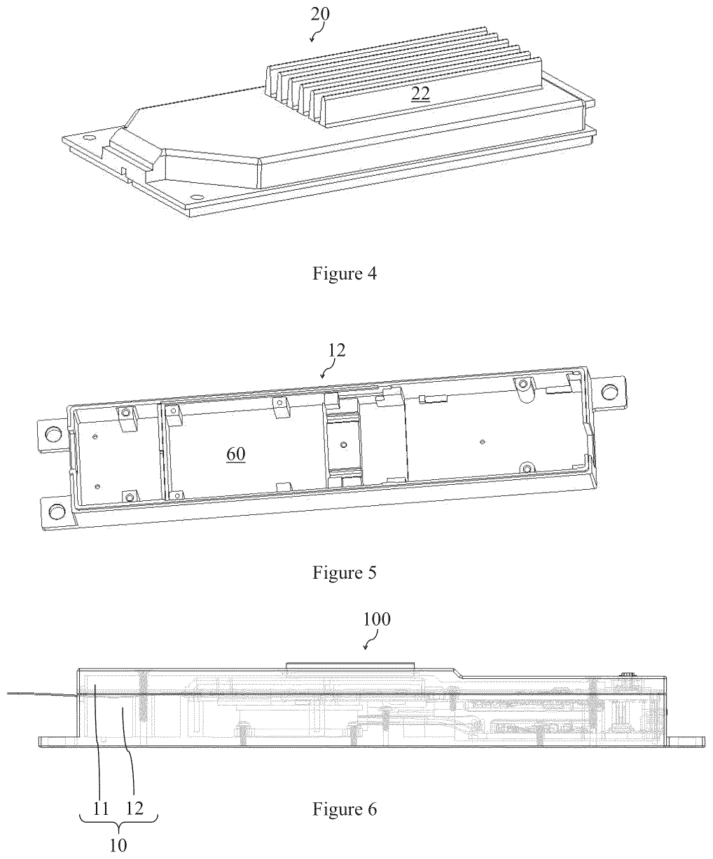

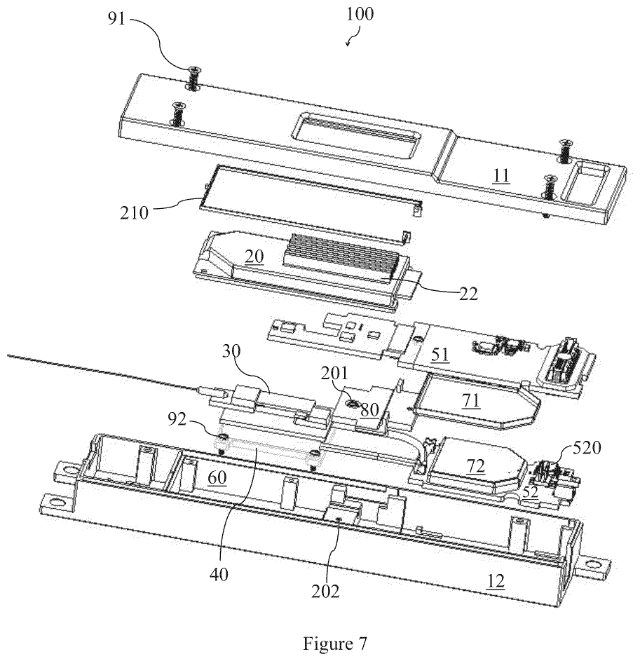

Referring to FIGS. 1 to 7, FIG. 1 shows a perspective view of a laser radar module 100 provided by a first embodiment of the present disclosure; FIG. 2 shows a perspective view on the basis of FIG. 1 after removal of a first outer housing 11; FIG. 3 shows a perspective view on the basis of FIG. 2 after removal of an upper cover 20 of a sealed chamber; FIG. 4 shows a perspective view of the upper cover 20 of the sealed chamber; FIG. 5 shows a perspective view of a second outer housing 12; FIG. 6 shows a front view of the laser radar module 100, in which the visible structures in the front view are shown by thicker lines, and the invisible structures in the front view are shown by thinner lines; and FIG. 7 shows an exploded view of the laser radar module 100. The laser radar module 100 may include: a housing body 10; a laser transceiver assembly 30 and a thermoelectric cooler (TEC) temperature control assembly accommodated in the housing body 10, the laser transceiver assembly 30 and the thermoelectric cooler temperature control assembly 40 being stacked and in contact with each other; an upper cover 20 of a sealed chamber accommodated in the housing body 10 and fixedly connected on an inner wall of the housing body 10, the upper cover 20 of the sealed chamber and the housing body 10 together enclose and seal the laser transceiver assembly 30; a circuit board accommodated in the housing body 10 and disposed side by side with the stacked laser transceiver assembly 30 and thermoelectric cooler temperature control assembly 40, and the circuit board is configured to electrically control the laser transceiver assembly 30 and the thermoelectric cooler temperature control assembly 40. In the present application, the housing body 10 and the upper cover 20 of the sealed chamber together enclose and seal the laser transceiver assembly 30 to achieve dustproof and waterproof protection of the laser transceiver assembly 30, and the circuit board is disposed side by side with the stacked laser transceiver assembly 30 and thermoelectric cooler temperature control assembly 40 in the housing body 10, so as to make full use of the space in the housing body 10 and facilitate the forming of a compact structure.

Although not shown in the figures, a single piece of circuit board may be used to electrically control the laser transceiver assembly 30 and the thermoelectric cooler temperature control assembly 40. In other embodiments, the circuit board may include a first circuit board 51 and a second circuit board 52 that are stacked and electrically connected to each other (for example through a second connector 520 of the second circuit board 52 as shown in FIG. 7) for electrically controlling the laser transceiver assembly 30 and the thermoelectric cooler temperature control assembly 40 respectively, the first circuit board 51 and the second circuit board 52 of the present application are arranged in a compact structure having stacked upper and lower layers, which is beneficial to the miniaturization and modularization of the laser radar module 100.

In some embodiments, the first circuit board 51 can be used to electrically control the emission and reception detection of the laser of the laser transceiver assembly 30, and the second circuit board 52 can be used to electrically control the on/off of the thermoelectric cooler temperature control assembly 40. In some embodiments, the cold end (upper surface shown in FIG. 7) of the thermoelectric cooler temperature control assembly 40 is in contact with the laser transceiver assembly 30 in order to cool down the laser transceiver assembly 30. In some embodiments, the first circuit board 51 can be a printed circuit board (rigid board, PCB) or a combination of a printed circuit board and a flexible circuit board (FPC).

In some embodiments, the housing body 10 includes a first outer housing 11 and a second outer housing 12 that are fixedly connected to each other (for example, through first screws 91 at four corners); the laser transceiver assembly 30, the thermoelectric cooler temperature control assembly 40, the first circuit board 51 and the second circuit board 52 are located between the first outer housing 11 and the second outer housing 12; the upper cover 20 of the sealed chamber and a portion of the second outer housing 12 together form the sealed chamber 60, and enclose and seal the laser transceiver assembly 30 and the thermoelectric cooler temperature control assembly 40. In some embodiments, the housing body 10 can be a metal structure, which has the functions of protecting the internal parts and electromagnetic shielding. In some embodiments, the thermoelectric cooler temperature control assembly 40 may be fixed on a bottom wall of the second outer housing 12, for example, through second screws 92 at four corners.

In some embodiments, the laser radar module 100 may further include a first electromagnetic shield 71 and a second electromagnetic shield 72 fixed on the first circuit board 51 and the second circuit board 52 respectively, the first electromagnetic shield 71 and the second electromagnetic shield 72 being located between the first circuit board 51 and the second circuit board 52. By disposing the first electromagnetic shield 71 and the second electromagnetic shield 72 between the first circuit board 51 and the second circuit board 52, the electromagnetic interference between the two can be reduced.

In some embodiments, the first outer housing 11 has a first opening 110, one side of the upper cover 20 of the sealed chamber facing away from the second outer housing 12 is provided with fins 22, and the fins 22 are exposed from the first opening 110. In some embodiments, the upper cover 20 of the sealed chamber can be a metal structure, and the fins 22 exposing from the first opening 110 can be beneficial to heat dissipation of the laser radar module 100.

In some embodiments, the first outer housing 11 may further include a fourth opening 114 that exposes a first connector 510 on the first circuit board 51.

In some embodiments, the laser radar module 100 may further include a support plate 80 fixed on the second outer housing 12 and supporting the first circuit board 51. In some embodiments, the support plate 80 can be fixed on the bottom wall of the second outer housing 12 through a third screw (not shown, accommodated in a first screw hole 201 of the support plate 80 and a second screw hole 202 of the second outer housing 12). In some embodiments, the support plate 80 can be a metal structure, and the support plate 80 is also a constituting part that forms the sealed chamber 60.

In some embodiments, the laser radar module 100 may also include a sealing rubber body 210, as shown in FIG. 7, provided at a position where the upper cover 20 of the sealed chamber and the second outer housing 12 are joined to each other in order to better ensure the sealing of the sealed chamber 60.

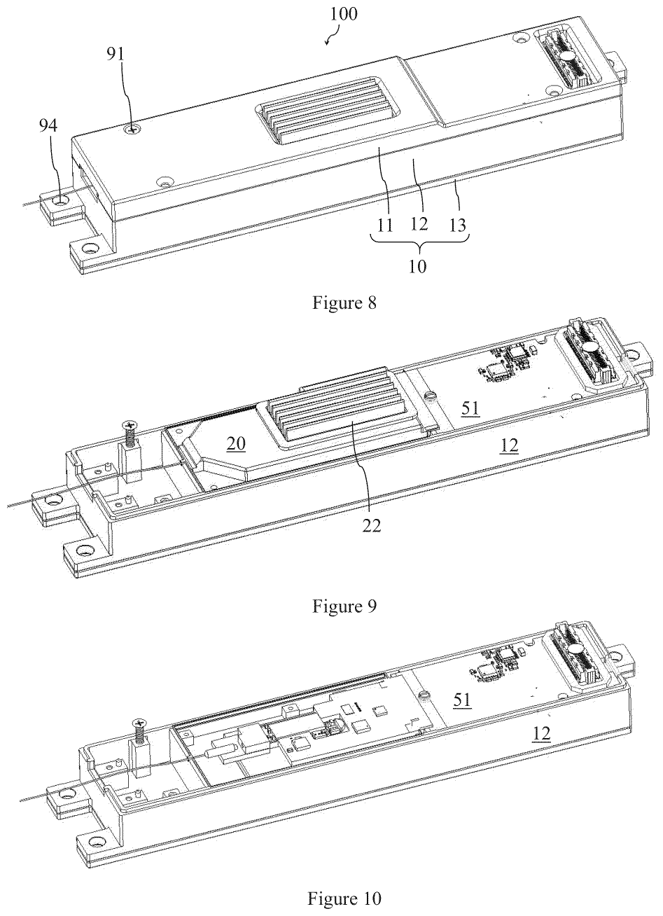

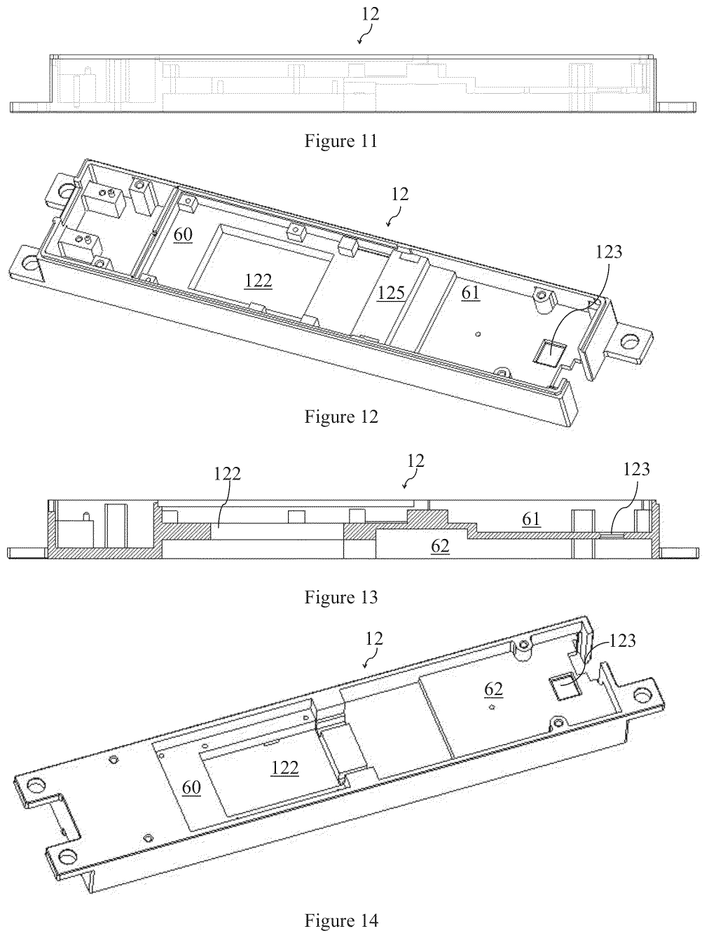

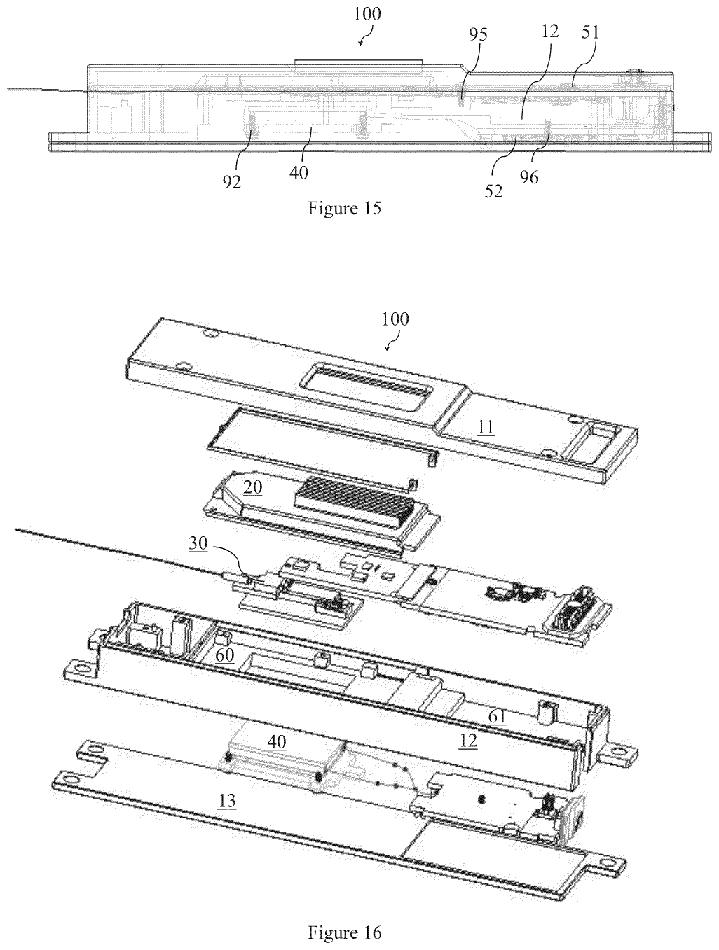

FIGS. 8 to 16 show an embodiment which is different from FIGS. 1 to 7. FIG. 8 shows a perspective view of the laser radar module provided by a second embodiment of the present disclosure; FIG. 9 shows a perspective view on the basis of FIG. 8 after removal of the first outer housing; FIG. 10 shows a perspective view on the basis of FIG. 9 after removal of the upper cover of the sealed chamber; FIG. 11 shows a front view of the second outer housing, in which the visible structures in the front view are shown by thicker lines, and the invisible structures in the front view are shown by thinner lines; FIG. 12 shows a perspective view of the second outer housing viewed from an upper side in FIG. 11; FIG. 13 shows a cross-sectional view of the second outer housing; FIG. 14 shows a perspective view of the second outer housing viewed from a lower side in FIG. 11; FIG. 15 shows a front view of the laser radar module, in which the visible structures in the front view are shown by thicker lines, and the invisible structures in the front view are shown by thinner lines; and FIG. 16 shows an exploded view of the laser radar module. The following content mainly describes the differences from the first embodiment, and the same or similar features will not be repeated. In the second embodiment, the housing body 10 may include a first outer housing 11, a second outer housing 12 and a third outer housing 13 that are fixed together, the second outer housing 12 is located between the first outer housing 11 and the third outer housing 13, the laser transceiver assembly 30 and the first circuit board 51 are located between the first outer housing 11 and the second outer housing 12, the thermoelectric cooler temperature control assembly 40 and the second circuit board 52 are located between the third outer housing 13 and the second outer housing 12, and the upper cover 20 of the sealed chamber and a portion of the second outer housing 12 (and a portion of the third outer housing 13) together form the sealed chamber 60, and enclose and scal the laser transceiver assembly 30 (and the thermoelectric cooler temperature control assembly 40). In the second embodiment, electromagnetic shielding between the first circuit board 51 and the second circuit board 52 can be achieved through the integrally formed second outer housing 12 itself, thereby simplifying the manufacturing and assembly process, and realizing the miniaturization of the laser radar module 100.

In some embodiments, the first outer housing 11 and the second outer housing 12 can be fixedly connected to each other through the first screws 91, and the second outer housing 12 and the third outer housing 13 can be fixedly connected to each other through fourth screws 94.

In some embodiments, the second outer housing 12 may include a second opening 122 and a third opening 123, the laser transceiver assembly 30 can be in contact with the thermoelectric cooler temperature control assembly 40 through the second opening 122, and the first circuit board 51 can be electrically connected to the second circuit board 52 through the third opening 123.

In some embodiments, the second outer housing 12 and the first outer housing 11 surround and form a first chamber 61 that accommodates the first circuit board 51, and the second outer housing 12 and the third outer housing 13 surround and form a second chamber 62 that accommodates the second circuit board 52.

In some embodiments, the sealed chamber 60 and the first chamber 61 can be separated by a step structure 125 (see FIG. 12) of the second outer housing 12 protruding toward the first circuit board 51.

In some embodiments, similar to the first embodiment, the laser radar module 100 may further include a sealing rubber body 210 provided at a position where the upper cover 20 of the sealed chamber and the second outer housing 12 are joined to each other.

Referring to FIG. 15, the thermoelectric cooler temperature control assembly 40 can be fixedly connected to the second outer housing 12 through the second screws 92, the first circuit board 51 can be fixedly connected to the second outer housing 12 through a fifth screw 95, and the second circuit board 52 can be fixedly connected to the second outer housing 12 through a sixth screw 96.

In the embodiments of the present application, the size of the laser radar module 100 with the integrated optical scanning assembly (laser transceiver assembly 30) is reduced to a centimeter level. This is beneficial to the miniaturization and modularization of the laser radar module 100, and can also greatly improve the compatibility of the laser radar module 100 with the entire mechanical system. The sealed chamber 60 in the embodiments of the present application forms an enclosure for protection and achieves the purpose of dustproof and waterproof; in particular, the integrated chamber structure design of the second embodiment can make the structure more compact and can simplify the assembly process. The first circuit board 51 and the second circuit board 52 in the embodiment of the present application make use of an upper and lower stacking design to reduce the size of the module, in addition, the setup of the first electromagnetic shield 71 and the second electromagnetic shield 72 as shown in the first embodiment can reduce electromagnetic interference; or, as shown in the second embodiment, the first circuit board 51 and the second circuit board 52 are simultaneously located in different chambers of the integrally formed second outer housing 12 which is made of metal, thereby reducing the size of the module while achieving the purpose of reducing electromagnetic interference.

The above descriptions are only preferred embodiments of the present disclosure and are not intended to limit the present disclosure. For those skilled in the art, the present disclosure may have various modifications and changes. Any modifications, equivalent substitutions, improvements, etc. made within the spirit and principles of the present disclosure shall be included in the scope of protection of the present disclosure.

What is claimed is:

1. A laser radar module, characterized by comprising:
a housing body;
a laser transceiver assembly and a thermoelectric cooler temperature control assembly, accommodated in the housing body, the laser transceiver assembly and the thermoelectric cooler temperature control assembly being stacked and in contact with each other;
an upper cover of a sealed chamber, accommodated in the housing body and fixedly connected on an inner wall of the housing body, the upper cover of the sealed chamber and the housing body together enclosing and sealing the laser transceiver assembly; and
a circuit board, accommodated in the housing body and disposed side by side with the stacked laser transceiver assembly and thermoelectric cooler temperature control assembly, and configured to electrically control the laser transceiver assembly and the thermoelectric cooler temperature control assembly.

2. The laser radar module according to claim 1, characterized in that,
the circuit board comprises a first circuit board and a second circuit board that are stacked and electrically connected to each other for electrically controlling the laser transceiver assembly and the thermoelectric cooler temperature control assembly respectively; the housing body comprises a first outer housing and a second outer housing that are fixedly connected to each other; the laser transceiver assembly, the thermoelectric cooler temperature control assembly, the first circuit board and the second circuit board are located between the first outer housing and the second outer housing; and the upper cover of the sealed chamber and a portion of the second outer housing together form the sealed chamber, and enclose and seal the laser transceiver assembly and the thermoelectric cooler temperature control assembly.

3. The laser radar module according to claim 2, characterized by further comprising:
a first electromagnetic shield and a second electromagnetic shield fixed on the first circuit board and the second circuit board respectively, the first electromagnetic shield and the second electromagnetic shield being located between the first circuit board and the second circuit board.

4. The laser radar module according to claim 2, characterized in that the first outer housing has a first opening, one side of the upper cover of the sealed chamber facing away from the second outer housing is provided with fins, and the fins are exposed from the first opening.

5. The laser radar module according to claim 2, characterized by further comprising:
a support plate, fixed on the second outer housing and supporting the first circuit board.

6. The laser radar module according to claim 1, characterized in that,
the circuit board comprises a first circuit board and a second circuit board that are stacked and electrically connected to each other for electrically controlling the laser transceiver assembly and the thermoelectric cooler temperature control assembly respectively; the housing body comprises a first outer housing, a second outer housing and a third outer housing that are fixed together, the second outer housing being located between the first outer housing and the third outer housing; the laser transceiver assembly and the first circuit board are located between the first outer housing and the second outer housing; the thermoelectric cooler temperature control assembly and the second circuit board are located between the third outer housing and the second outer housing; and the upper cover of the sealed chamber and a portion of the second outer housing together form the sealed chamber, and enclose and seal the laser transceiver assembly.

7. The laser radar module according to claim 6, characterized in that the second outer housing comprises a second opening and a third opening, the laser transceiver assembly is in contact with the thermoelectric cooler temperature control assembly through the second opening, and the first circuit board is electrically connected to the second circuit board through the third opening.

8. The laser radar module according to claim 6, characterized in that the second outer housing and the first outer housing surround and form a first chamber that accommodates the first circuit board, and the second outer housing and the third outer housing surround and form a second chamber that accommodates the second circuit board.

9. The laser radar module according to claim 8, characterized in that the sealed chamber and the first chamber are separated by a step structure of the second outer housing protruding toward the first circuit board.

10. The laser radar module according to claim 6, characterized by further comprising:
a sealing rubber body, provided at a position where the upper cover of the sealed chamber and the second outer housing are joined to each other.
